(19) United States
(12) Patent Application Publication
(10) Pub. No.: US 2020/0082995 A1
(43) Pub. Date: Mar. 12, 2020

(54) CHALCOPYRITE-PEROVSKITE PN-JUNCTION THIN-FILM PHOTOVOLTAIC DEVICE

(71) Applicant: Ascent Solar Technologies, Inc., Thornton, CO (US)

(72) Inventor: Lawrence M. Woods, Littleton, CO (US)

(21) Appl. No.: 16/562,895

(22) Filed: Sep. 6, 2019

Related U.S. Application Data
(60) Provisional application No. 62/727,662, filed on Sep. 6, 2018.

(51) Int. Cl. H01G 9/20; H01G 9/00; H01L 51/42; H01L 51/44; H01L 51/00

(52) U.S. Cl. CPC H01G 9/2009; H01G 9/0036; H01L 51/0077; H01L 51/442; H01L 51/0014; H01L 51/4213

(57) ABSTRACT

A thin-film photovoltaic device includes: a substrate for supporting the thin-film photovoltaic device; a back contact layer disposed on the substrate; a p-type solar absorber layer disposed on the back contact layer, the p-type solar absorber layer including one of a Group IB-IIIA-VIA.sub.2 material and a IIB-VIA material; an n-type solar absorber layer disposed on and in contact with the p-type solar absorber layer, the n-type solar absorber layer including one of a Group IA-IVA-VIIA.sub.3 material, a Group IA.sub.2.-IVA-VIIA.sub.6, and a Group I.sub.2.-I-IIIA-VIIA.sub.6 material; and a semi-transparent top contact layer disposed on the n-type solar absorber layer.

### CROSS-REFERENCES TO RELATED APPLICATIONS

This application claims the benefit of priority to U.S. Provisional Application No. 62/727,662, entitled “CHALCOPYRITE-PEROVSKITE PN-JUNCTION THIN-FILM PHOTOVOLTAIC DEVICE”, filed Sep. 6, 2018, the contents of which are incorporated herein by reference in their entireties.

### FIELD OF THE INVENTION

The present invention relates to the design and fabrication of photovoltaic devices, and more specifically to the combining of two solar absorber layers together into a single junction photovoltaic device.

### BACKGROUND

Photovoltaic (“PV”) devices generally include one or more materials capable of generating an electric potential and current upon exposure to light, and electrical contacts constructed on a suitable substrate that are used to draw off electric current resulting from absorption of light within the photo-active PV material.

Photovoltaic cells having a variety of characteristics have been developed. One class of photovoltaic cells that is currently the subject of significant research and commercialization is the thin-film class. Thin-film photovoltaics (“TFPV”) include a plurality of layers of thin films formed on a substrate.

TFPV devices are commonly distinguished from their thicker single-crystal PV counterparts in their ability to absorb light in relatively thin layers, and their ability to function well when fabricated using low-cost deposition techniques, and upon a variety of substrates, including low-cost, lightweight and flexible substrates. Thus, TFPV devices are being considered for a variety of applications where weight and flexibility are important, such as aerospace, portable power, building integrated photovoltaics, and building applied photovoltaics.

TFPV devices commonly include an inorganic solar absorber layer formed of a Group IIB-VIA material (e.g. CdTe in a zinc-blende structure), or a Group IB-IIIA-VIA.sub.2 material (e.g. CuInSe.sub.2 in a chalcopyrite crystalline structure), or an amorphous group IVA material (e.g amorphous Si), or more recently Group IA-IVA-VIIA.sub.3 material (e.g CsPbI.sub.3 in a perovskite structure), and Group IA.sub.2.-IVA-VIIA.sub.6 material (e.g. Cs.sub.2SnI.sub.6 in a vacancy-ordered double perovskite structure), where each Group number is associated with the electron filling of the outermost atomic orbital. However, a solar absorber layer can be formed of other materials, including the recent hybrid organic-inorganic class of perovskites, where the Group IA element is replaced by an organic molecule (e.g. methyl-ammonium). The term Group IIB-VIA material refers to a compound having a photovoltaic effect that is formed from at least one element from each of groups IIB and VIA of the periodic table. In the context of this disclosure, Group II elements include Zinc, Cadmium, and Group VIA elements include Sulfur, Selenium, and Tellurium. The term Group IIIA-VA material refers to a compound having a photovoltaic effect that is formed from at least one element from each of groups IIIA and VA of the periodic table. In the context of this disclosure, Group VA elements include Nitrogen, Phosphorous, Arsenic, Antimony, and Bismuth. The term Group IB-IIIA-VIA.sub.2 material refers to a compound having a photovoltaic effect that is formed of at least one element from each of groups IB, IIIA, and VIA of the periodic table, where there are two atoms of the group VIA element for every one atom of the group IB and IIIA elements. In the context of this disclosure, Group IB elements include Copper, Silver, and Gold, and Group IIIA elements include Boron, Aluminum, Gallium, Indium, and Thallium. The term Group I-IVA-VIIA.sub.3 material refers to a compound having a photovoltaic effect that is formed of at least one element from each of groups I (A or B), IVA, and VIIA of the periodic table, where there are three atoms of the group VIIA element for every one atom of the group I and IVA elements. The Group I elements include Sodium, Potassium, Rubidium, and Cesium, but can also include Copper, Silver, and Gold. It is well known in the art that the Group I elements can be substituted with organic molecules including methyl-ammonium, phenyl-ethyl-ammonium, and Formamidinium, to form hybrid organic-inorganic perovskite solar cells that have produced the highest efficiency perovskite based devices to date. The Group IVA elements include Silicon, Germanium, Tin, and Lead, and the Group VIIA elements include Iodine, Bromine, Chlorine, and Fluorine. In the case of the Group I.sub.2.-IV-VIIA.sub.6 (e.g. double perovskite) material, the Group IV element can be replaced by a Group I element and a Group IIIA element, or a Group I.sub.2.-I-IIIA-VIIA.sub.6. Furthermore the Group IIIA can also be replaced with a Group VA element including Antimony and Bismuth, but that is in a +3 oxidation state.

TFPV devices commonly are multi-layered devices with each layer including a different material. In a single-junction TFPV device, it is common that the n-type layer with n-type conductivity includes one semiconductor material, and p-type layer with p-type conductivity includes another semiconductor material, which when the two semiconductors are put into contact with one another, then form a PN-heterojunction. This is to be distinguished from a PIN-junction, where there is an intrinsic layer, or i-layer, with little or no conductivity or conductivity type, sandwiched between the p-type layer and the n-type layer.

The material parameters and characteristics for the n-layer and p-layer in an optimal PN-heterojunction are different than the n-layer and p-layer in an optimal PIN junction. For example, the optimal free-carrier concentrations for the p- and n-layers are typically orders of magnitude higher in a PIN, or NIP, junction, compared to a PN heterojunction, so that a sufficiently strong electric field can be maintained across the solar-absorbing i-layer that aids in the extraction of photo-generated free-carriers from within the i-layer. The high free-carrier concentration then requires that the p- and n-layers of the PIN junction to be sufficiently thin to avoid excessive free-carrier absorption and minority-carrier recombination. For the PN-heterojunction, the free-carrier absorption and minority-carrier recombination drive n- and p-layers to lower free-carrier concentrations, as one of the layers has to perform as the solar absorbing layer and thus cannot be too thin. Not all p- and n-type semiconductor materials can be formed with sufficiently high free-carrier concentrations for PIN junction devices, or even the moderate concentrations of free-carriers that would optimize a PN heterojunction, due to intrinsic defect properties such as compensating defects. Furthermore, given the polycrystalline nature of TFPV, there is great difficulty in achieving tightly controlled intentional doping and diffusion of impurities in the presence of grain boundaries, which act as conduits for diffusion. Another difference between PIN and PN-heterojunctions include the absorption coefficients of the p- and n-layers since the i-layer is the solar absorbing layer in a PIN junction, but the n- or p-layer is the solar absorbing layer in typical PN-heterojunction TFPV. Another difference is the carrier extraction role that the n- and p-layers have in a PIN junction that requires appropriate valence band energy line-ups between the p- and i-layers, and the conduction band energy line-up between the i- and n-layers. With PN-heterojunctions, the conduction and valence band energy line-ups between the p- and n-layers requires appropriate band line-ups to avoid current blocking and excessive recombination at the hetero-interface.

Typical Group IB-IIIA-VIA.sub2 TFPV devices, for example Copper Indium Gallium Di-Selenide (CIGS), are of the PN-heterojunction type with CIGS as the p-type solar absorber layer, and a thin layer of CdS as the n-type layer. Conversely, typical Group I-IVA-VIIA.sub.3 TFPV devices, hereinafter referred to as perovskites, are of the PIN-junction type, since the Group I-IVA-VIIA.sub.3 solar absorber materials are typically intrinsic in nature. The typical layer structure for each device is shown in FIGS. 1a and 1b.

The typical layer structure of CIGS TFPV devices (FIG. 1a) include metallic Mo back contacts that form a low resistance Schottky barrier contact to the CIGS solar absorber. The n-type heterojunction partner layer to the CIGS is typically a thin layer of CdS, which traditionally has yielded the highest efficiencies, although other non-Cd containing layers, for example Zn(O,S), or ZnSnO, or In₂(O,S)₃ are being developed to avoid Cd related toxicity issues. Back up buffer layers such as intrinsic or low-conductivity ZnO are typically deposited on top of the thin CdS layer in order to add protection against shorting, while also avoiding some solar absorption losses that a thicker layer of CdS by itself would present. Top layers are transparent conducting oxides that typically include InSnO, also known as ITO, or doped ZnO, such as ZnO:Al.

Typical perovskite TFPV devices (FIG. 1b) have intrinsic perovskite layers that are sandwiched between an n-type electron transport material, hereinafter referred to as ETM, and a p-type hole transport material, hereinafter referred to as HTM to form the PIN-junction. Most ETMs and HTMs are organic-based, but can also be metal oxides. Some examples of ETM's from the literature are phenyl-C61-butyric acid methyl ester (otherwise known as PCBM), titanium oxide (TiOx), ZnO (zinc oxide), or tin oxide (SnO₂). Some examples of HTM's from the literature are poly-3-hexyl thiophene (otherwise known as P3HT), 2,2′,7,7′-Tetrakis[N,N-di(4-methoxyphenyl)amino]-9,9′-spirobifluorene (otherwise known as spiro-OMeTAD), poly(3,4-ethylenedioxythiophene)-poly(styrenesulfonate) (otherwise known as PEDOT:PSS), and molybdenum oxide (MoOx). The contact layers next to the ETM are typically transparent conducting oxides such as fluorinated SnO₂ or ITO. The contact layer next to the HTM is typically an opaque metal such as Al or Au, or a transparent conducting oxide such as ITO or fluorinated SnO₂.

### SUMMARY

In an embodiment, a thin-film photovoltaic device includes a substrate for supporting the thin-film photovoltaic device. A metallic back contact layer or multi-layer is disposed on the substrate and is in contact with the substrate. A p-type Group IB-IIIA-VIA.sub.2 solar absorber layer is disposed on the back contact layer, and is of at least 0.5 microns thick to enable absorption of most of the sunlight that reaches the layer. A second solar absorber layer that is an n-type perovskite solar absorber layer with n-type conductivity and that is between 0.03 and 0.6 microns thick is disposed on and is in contact with the p-type Group IB-IIIA-VIA.sub.2 solar absorber layer, and forms a PN heterojunction with the p-type Group IB-IIIA-VIA.sub.2, and the two layers combine to absorb nearly all the sunlight reaching these absorber layers. The n-type perovskite solar absorber has a bandgap that is greater than the p-type Group IB-IIIA-VIA.sub.2 solar absorber, but is less than 1.85 eV, and has a free carrier concentration that is between 1e15 cm⁻³ and 1e18 cm³. A semi-transparent buffer layer is optionally disposed upon and is in contact with the n-type perovskite layer. A semi-transparent top contact layer is disposed on and is in contact with the semi-transparent buffer layer (if optionally applied), or disposed on and in contact with the n-type perovskite layer. In an embodiment, the p-type Group IB-IIIA-VIA.sub.2 solar absorber is CuInSe₂ or a CuInSe₂ alloy with at least one of Ag, Ga, Al, S, or Te. In another embodiment, the n-type perovskite solar absorber is Cs₂SnI₆ double perovskite, or a Cs₂SnI₆ alloy with Rb for Cs, or a Cs₂SnI₆ alloy with Br for I, or a Cs₂SnI₆ alloy with Rb for Cs, Ti for Sn, and Br for I. In another embodiment, the n-type perovskite is an X₂Y′Y″Z₆ double perovskite with X═Cs or Rb, Y′═Cu, or Ag, or In, and Y″═In, Ga, Sb, or Bi, and Z═Cl, Br, or I. In another embodiment, the n-type perovskite is a hybrid organic-inorganic double perovskite, with the Group I or X element being an organic molecule.

In an embodiment, the optional buffer layer is ZnO, or an alloy of ZnO that includes Zn(O,S), or ZnSnO, or ZnInO, or ZnMgO.

In an embodiment, the n-type perovskite is deposited by co-evaporation, and is in-line and within the same vacuum deposition system as the deposition of the p-type Group IB-IIIA-VIA.sub.2 solar absorber.

In an embodiment, the p-type Group IB-IIIA-VIA.sub.2 solar absorber is deposited in sublayers from a multi-zone vacuum deposition system, and ion-beam surface smoothing is performed prior to the final sublayer deposition.

### BRIEF DESCRIPTION OF THE FIGURES

FIG. 1a-1b shows a cross-sectional schematic view of a typical CIGS device in the art (PN-heterojunction) in (FIG. 1a) and a typical perovskite device in the art (PIN junction) in (FIG. 1b).

FIG. 2 shows a cross-sectional schematic view of one embodiment of the present invention that is designed as a dual absorber chalcopyrite-perovskite PN-heterojunction device, in accordance with an embodiment.

FIG. 3 shows a flowchart illustrating one process for fabricating one dual absorber chalcopyrite-perovskite PN-heterojunction TFPV device shown in FIG. 2.

FIG. 4 shows a table of the device modeling results for both a traditional CdS/CIGS TFPV device and for a dual absorber chalcopyrite-perovskite PN-heterojunction TFPV device.

FIG. 5 shows a plot of the device efficiency versus the p-type CIGS solar absorber thickness for both a traditional CdS/CIGS TFPV device and for a dual absorber chalcopyrite-perovskite PN-heterojunction TFPV device, and as a function of the Interface Defect Density (IDD).

FIG. 6 shows a plot of the modeled Quantum Efficiency (QE) for a dual absorber chalcopyrite-perovskite PN-heterojunction TFPV device, and as a function of the CIGS solar absorber layer thickness, in accordance with an embodiment.

FIG. 7 shows a plot of the modeled Quantum Efficiency (QE), for both a traditional CdS/CIGS TFPV device and for a dual absorber chalcopyrite-perovskite PN-heterojunction TFPV device, and as a function of the Interface Defect Density (IDD), in accordance with an embodiment.

### DETAILED DESCRIPTION

The present invention may be understood by reference to the following detailed description taken in conjunction with the drawings briefly described below. It is noted that, for purposes of illustrative clarity, certain elements in the drawings may not be drawn to scale.

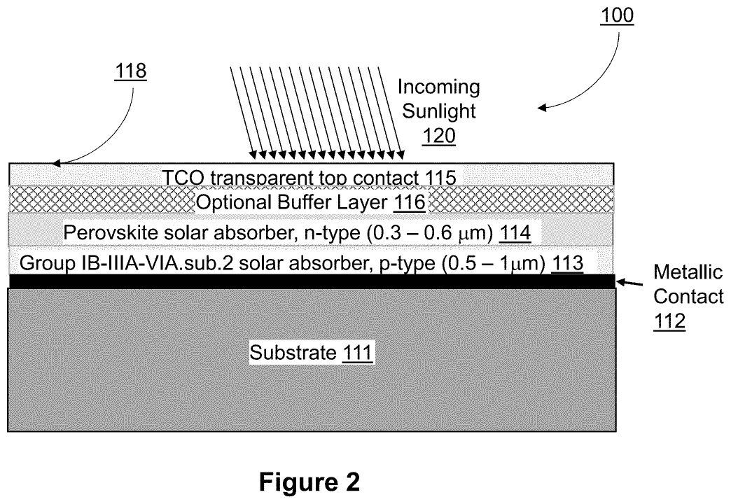

TFPV solar cells based upon a PN heterojunction design with two light-absorbing materials that include a p-type chalcopyrite and an n-type perovskite (FIG. 2) may provide low cost photovoltaic technology that may be deposited on lightweight and flexible substrates for high efficiency (W/m²) and specific power (W/Kg) characteristics. The device design enables higher efficiency, lower cost, and lower toxicity TFPV devices, as compared to prior art TFPV devices, due to the design that utilizes each solar absorber's good qualities while eliminating or reducing each other's downsides.

The dual absorber PN heterojunction device design that includes an n-type solar absorbing perovskite enables cost reductions in at least three ways. First, a high quality n-type perovskite solar absorber enables a thickness reduction of the more costly chalcopyrite based solar absorber layer (e.g. CuInSe.sub.2). Second, an n-type perovskite solar absorber that is at least 6 times thicker than typical 50 nm CdS, could enable elimination of the ZnO based buffer layer and its associated processing step. Third, an n-type perovskite solar absorber (non-Pb containing) also eliminates the Cd toxicity issue along with associated waste mitigation and disposal costs of a typical CdS n-type heterojunction partner layer to a p-type CuInSe.sub.2 based device. The efficiency benefit of substituting an n-type perovskite in place of traditional CdS or other wide-bandgap n-type layers is enabled from the perovskite that is selected with a lower bandgap than CdS, to absorb more light, combined with the lower defect density that is typically measured in perovskite materials, which reduces recombination within the n-type layer.

An advantage of the dual absorber PN heterojunction device design that utilizes a p-type chalcopyrite solar absorber versus traditional PIN structure device with only intrinsic perovskite solar absorbers, is that the p-type chalcopyrite solar absorber offers a low bandgap that can absorb longer wavelength light that typically passes through typical perovskite solar absorber PIN devices, as the higher quality intrinsic perovskite solar absorbers are typically with higher bandgaps. In addition, having a second p-type chalcopyrite solar absorber enables use of lesser quality perovskite solar absorber materials (example: double perovskites) that would otherwise render a typical perovskite-based device with PIN structure as low efficiency. In addition, the p-type chalcopyrite offers a more stable device layer due to the inherent stability of the chalcopyrite p-type layer.

FIG. 2 shows a cross-sectional schematic view of a PN heterojunction TFPV device 100 that is fabricated with two solar absorber layers including of a p-type Group IB-IIIA-VIA.sub.2 (e.g., CuInGaSe₂, also known as CIGS), solar absorber material 113 and an n-type perovskite solar absorber layer 114. TFPV device 100 also has a substrate 111, a back contact layer 112 that is deposited directly on the substrate and that may be Mo in CuInGaSe₂ based PN heterojunctions. Back contact layer 112 is shown as a single layer that is Mo, but optionally may be a multi-layer back contact, or a semi-transparent back contact material. The p-type Group IB-IIIA-VIA.sub.2 (e.g., CuInGaSe₂), solar absorber material 113 is deposited on and is in direct contact with the back contact layer. The n-type perovskite solar absorber layer 114 is deposited on and is in direct contact with p-type Group IB-IIIA-VIA.sub.2 solar absorber, forming a PN heterojunction. Top contact layer 115 is deposited on and in contact with the n-type perovskite solar absorber 114, and in certain embodiments, includes ITO (InSnO) or ZnO:Al (or ZnO:In or ZnO:Ga or ZnO:B), or fluorine doped SnO₂, transparent conducting oxides that are typical for CIGS based PN heterojunctions, and perovskite based PIN junctions. Optional buffer layer 116 may be fabricated on top of and in contact with the n-type perovskite solar absorber 114, and before the top contact layer 115.

As shown, TFPV device 100 is formed in a substrate configuration with substrate 111 located below back contact 112 (relative to the direction of primary light incidence 120 upon a top surface 118 of TFPV device 100). Substrate 111 may be rigid or flexible. Substrate 111 may, for example, be formed of at least one of glass, thin flexible glass, a metal foil, silicone, silicone resin, reinforced silicone, reinforced silicone resin, and high temperature capable polyimide. It should be understood that in some embodiments the device of the present invention may also be formed in the superstrate configuration, with light incident through the substrate, when the substrate and back contact are semi-transparent to the solar spectrum.

Back contact 112 may, for example, be fabricated of Mo, onto substrate 111 but optionally may be a multi-layer back contact, such as that described by Woods et al. (U.S. Pat. Nos. 9,780,242, 9,219,179, and 9,209,322). The back contact may optionally be a semi-transparent back contact material or semi-transparent multi-layer that enables direct solar light collection, or bifacial light collection when combined with a semi-transparent substrate. A semi-transparent back contact may, for example, be conductive electrodes including TCOs such as ZnO:Al, Indium Tin Oxide (ITO), or doped SnO₂, or a similarly transparent conducting material such as Stannates, or transparent layers with carbon nanotubes or metallic nanowires. Optional semi-transparent contact interface layer (not shown) may, for example, be deposited on the semi-transparent back contact and as taught by Woods et al. (U.S. Pat. No. 8,124,870, and related application publications: US20160225928, and US20120160313).

A Group IB-IIIA-VIA.sub.2 p-type material (e.g., solar absorber 113) is deposited onto back contact 112. Solar absorber 113 may optionally have a near surface region that is n-type, due to the formation of a different phase from the p-type bulk phase. Deposition of solar absorber 113 may, for example, be achieved by means of co-evaporation, thermal evaporation, spraying, printing, or other thin-film deposition techniques and may contain selenides, sulfides, and tellurides of Cu, Ag, Al, Ga, In, and their alloys. In one example, solar absorber 113 may be a variation of Cu(In,Ga,Al)(Se,S)₂ such as CIGS. The high-temperature step in the CIGS deposition and chalcopyrite formation process is critical to achieving a high quality solar absorber layer, and likely requires that it be deposited before the n-type perovskite heterojunction partner layer 114 given the more temperature sensitive perovskite materials. Conversely, the Group IB-IIIA-VIA.sub.2 p-type material is more stable at the lower temperature deposition process of the n-type perovskite solar absorber layer. The bandgap of the Group IB-IIIA-VIA.sub.2 p-type material is determined by the elements selected and their subsequent degree of alloying, which is well documented in the literature. With the incident sun light filtered by the n-type perovskite solar absorber layer, then it is advantageous to select a Group IB-IIIA-VIA.sub.2 layer bandgap that is lower than the bandgap of the n-type perovskite solar absorber to maximize the total solar absorption. In an embodiment, the bandgap of the p-type Group IB-IIIA-VIA.sub.2 solar absorber 113 is between 1.0 and 1.3 eV. In another embodiment, the p-type Group IB-IIIA-VIA.sub.2 solar absorber 113 is CuInGaSe₂ (CIGS). Given that the filtered light will be primarily longer wavelengths of the solar spectrum, then it is advantageous to increase the thickness of the Group IB-IIIA-VIA.sub.2 solar absorber as costs allow. The presence of the lower cost n-type perovskite solar absorber will change the device efficiency versus cost trade-off with thickness, enabling thinner Group IB-IIIA-VIA.sub.2 solar absorbers with higher efficiencies compared to traditional CIGS based devices. In an embodiment, the thickness of the Group IB-IIIA-VIA.sub.2 solar absorber 113 is less than 1.0 microns.

A smooth p-type Group IB-IIIA-VIA.sub.2 solar absorber surface would be beneficial to forming a better PN heterojunction with the N-type perovskite solar absorber layer. In an embodiment, the p-type Group IB-IIIA-VIA.sub.2 solar absorber is deposited in sublayers from a multi-zone vacuum deposition system, and ion-beam surface smoothing is performed prior to the final sublayer deposition. The final sublayer is typically the thinnest sublayer, thus minimizing its effect on the surface roughness, and its high-temperature deposition acts to anneal out surface and near surface defects caused by the ion-beam smoothing treatment just before it.

An n-type perovskite solar absorber layer 114 is deposited onto p-type Group IB-IIIA-VIA.sub.2 solar absorber material (e.g., solar absorber 113) with optional near surface region that is n-type. Deposition of n-type perovskite solar absorber layer 114 may, for example, be achieved by means of co-evaporation, thermal evaporation, spraying, printing, chemical bath deposition (CBD), chemical vapor deposition, spin-coating, sputtering, or other known techniques. The n-type perovskite layer 114 is, for example, Cs₂SnI₆ or its alloys with Br, or the Rubidium variant Rb₂SnI₆ and its alloys with Br. These vacancy-ordered double perovskite structures are more prone to be n-type due to their native defect structure versus the simpler ‘single’ perovskite structure that are prone to be intrinsic or lightly p-type. These double perovskites can also have bandgaps and carrier concentrations that would be suitable for a high-efficiency PN-heterojunction device when mated with a p-type Group IB-IIIA-VIA.sub.2 solar absorber. The bandgaps of these double perovskites have been reported to be in the range of 1.3 to 1.8 eV, and with n-type carrier concentrations in the range of 1e15 to 5e17 cm⁻³. Further adding to their suitability is the reported values of electron affinity that are similar to CIGS solar absorbers, and high free-carrier mobility's indicating good electronic quality. The dual solar absorber PN-heterojunction design allows for some compromising of the perovskite solar absorber electronic quality that would be otherwise be more catastrophic to the performance of single perovskite solar absorber layers in a PIN device structure. Hence the dual solar absorber PN-heterojunction design enables the use of these double-perovskites that would otherwise be unsuitable for the consideration as a high-efficiency material for PIN device structures with single perovskite solar absorbers due to their n-type character and lower electronic quality. In an embodiment, the n-type perovskite solar absorber layer 114 is a Group IA.sub.2.-IV-VIIA.sub.6 double perovskite. In an embodiment, the n-type perovskite solar absorber layer 114 is an n-type perovskite heterojunction partner layer. In an embodiment, the n-type perovskite heterojunction partner layer is Cs₂SnI₆ or its alloys with Br, or the Rubidium variant Rb₂SnI₆ and its alloys with Br. In an embodiment the n-type perovskite heterojunction partner layer is Cs₂TiI₆ or its alloys with Br, or the Rubidium variant Rb₂TiI₆ and its alloys with Br. In another embodiment, the n-type perovskite solar absorber 114 is a hybrid organic-inorganic double perovskite, with the Group 1 element being substituted with an organic molecule. In an embodiment, the bandgap of the n-type double perovskite 114 is between 1.3 and 1.65 eV. In another embodiment, the bandgap of the n-type double perovskite is between 1.65 and 1.85 eV. In an embodiment, the n-type carrier concentration of the double perovskite is between 1e15 to 1e18 cm⁻³. In an embodiment, the n-type carrier concentration of the double perovskite is between 5e15 to 5e17 cm³.

Another potential n-type perovskite PN-heterojunction solar absorber layer 114 is a Group I.sub.2.-I-IIIA-VIIA.sub.6 double perovskite. Another example of this layer is Cs₂AgInBr₆, with reported bandgaps less than 1.6 eV and n-type conductivity. Furthermore the Group IIIA can also be replaced with a Group VA element including Antimony and Bismuth, but that is in a +3 oxidation state. In an embodiment, the n-type perovskite solar absorber 114 is an X₂Y′Y″Z₆ double perovskite with X═Cs or Rb, Y′═Cu, or Ag, or In, and Y″═In, Ga, Sb, or Bi, and Z═Cl, Br, or I. In another embodiment, the n-type perovskite solar absorber 114 is a hybrid organic-inorganic double perovskite, with X═organic molecule.

The thickness of the n-type perovskite solar absorber layer 114 is designed to absorb the majority of the solar spectrum, given its position above the p-type solar absorber layer. However, thinner layers than what is typically used in PIN device structures are still able to produce good performance due to the p-type solar absorber beneath. Furthermore, if an optional buffer layer (116) is included in the PN-heterojunction design, then n-type layer down to 30 nm can still result in good performance. In an embodiment, the thickness of the n-type perovskite solar absorber 114 is between 30-70 nm. In another embodiment, the n-type perovskite solar absorber 114 is between 70-300 nm. In another embodiment, the n-type perovskite solar absorber 114 is between 300-600 nm.

The optional buffer Layer 116, if included, may, for example, be deposited by chemical bath deposition (CBD), chemical vapor deposition and its more precise variant: atomic layer deposition, sputtering, or other technique. The optional buffer layer can act as a back-up n-type heterojunction partner layer when the thickness of the n-type perovskite solar absorber is inadequate, (ex. pinholes) and otherwise allowing a significant shunt or direct short of electrical current from the p-type solar absorber to the top contact layer. It can also act to protect the n-type perovskite solar absorber from the sometimes harsh deposition conditions of the top contact transparent conducting oxide (TCO) (115). However the bandgap of the optional buffer layer does not enable it to be a significant solar absorber layer, and it passes most of the incident solar spectrum to the underlying solar absorber(s). In an embodiment, the optional buffer layer 116 is ZnO, or an alloy of ZnO that includes of Zn(O,S), or ZnSnO, or ZnInO, or ZnMgO.

Top contact layer 115 may be deposited onto the n-type perovskite solar absorber layer 114 or optional buffer layer 116 and is mostly transparent to the solar spectrum. In one example, top contact layer 115 is a TCO and includes of ITO (InSnO) or ZnO:Al (or ZnO:In or ZnO:Ga or ZnO:B), or fluorine doped SnO₂, transparent conducting oxides that are typical for CIGS based PN heterojunctions, and perovskite based PIN junctions. Top contact layer 115 may also be similarly transparent conducting materials such as Stannates, or transparent layers with carbon nanotubes, or silver nanowires, or copper nanowires, or copper mesh. In the event that the back contact 112 is a semi-transparent back contact material or semi-transparent multi-layer that when combined with a semi-transparent substrate enables direct solar light collection through the substrate, then the top contact layer may optionally be an opaque metallic layer. The top contact layer 115 is deposited onto the optional buffer or directly onto n-type perovskite solar absorber layer by means of sputtering, chemical vapor deposition or other thin-film deposition technique.

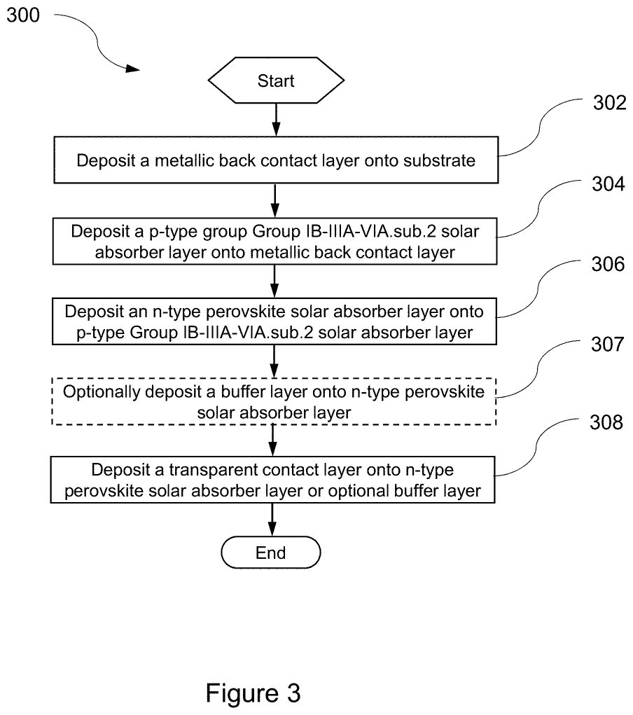

FIG. 3 is a flowchart illustrating one example of a process 300 of fabricating a chalcopyrite-perovskite PN-heterojunction TFPV device (e.g., TFPV device 100, FIG. 2). A back contact layer 112 is deposited, in step 302, onto the substrate 111. In one example of step 302, back contact layer 112 is Mo and is deposited onto substrate 111 made of high-temperature capable polyimide. A p-type Group IB-IIIA-VIA.sub.2 solar absorber layer 113 is deposited, in step 304, onto the back contact interface layer deposited in step 302. In one example of step 304, Group IB-IIIA-VIA.sub.2 solar absorber layer 113 is CuInGaSe₂.

In step 306, an n-type perovskite solar absorber layer is deposited onto the Group IB-IIIA-VIA.sub.2 solar absorber layer 113 deposited in step 304. In one example of step 306, the n-type perovskite solar absorber layer 114 is Cs₂SnI₆, and is deposited onto solar absorber layer 113, which is CuInGaSe₂. Step 307 is optional. In step 307, a buffer layer is deposited onto the n-type perovskite solar absorber layer of step 306. In one example of step 307, buffer layer 116 is ZnO, and is deposited onto n-type perovskite solar absorber layer 114, which is Cs₂SnI₆. A semi-transparent top contact layer is deposited, in step 308, onto the n-type perovskite solar absorber layer of step 306 (or the buffer layer of step 307, if included). In one example of step 308, top contact layer 115 is ITO and is deposited onto n-type solar absorber layer 114, which is Cs₂SnI₆.

### Device Modeling Results

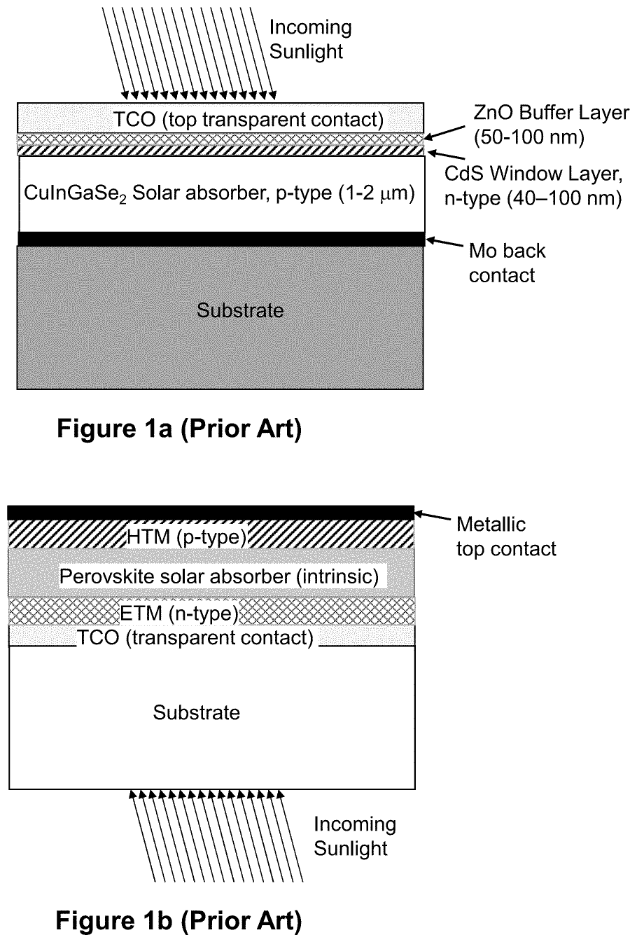

To help validate the potential advantages of the Chalcopyrite-Perovskite dual solar absorber PN-heterojunction concept described herein, device modeling and emulation was performed using wxAMPs software. Device modeling and emulation was also performed on the traditional CIGS TFPV device structures for comparison purposes. The standard or traditional CIGS Device construction is shown in cross-section in FIG. 1a and written out as follows: ZnO:Al/iZnO/CdS (50 nm)/Rec. layer/CIGS/ohmic back contact. The only differences with FIG. 1a is the omission of a specific back contact material, replaced with an ohmic quality contact, and the added thin recombination layer (Rec. layer) that was placed between the CdS and CIGS layers to represent a population of defects at the CdS-CIGS heterojunction interface that exists for all heterojunctions. This hetero-interface defect density, which can be difficult to quantify and know ahead of time, can have a significant effect on the device performance. Some factors affecting the defect density and quality of the interface are: lattice mismatch, alternative surface phases, conduction and valence energy band line-ups, ionicity of each of the materials, and impurities that may accumulate at the interface. For the model, it was assumed that the bandgap and electron affinity controlled the energy band line-ups, and given the difficulty in predicting interface defect densities, then varying levels of the interface defect density were modeled to get an overall perspective of its effect for the two different devices modeled. The interface defect densities were placed at the mid-bandgap energy level of the CIGS. Similarly for the dual absorber Chalcopyrite-Perovskite PN heterojunction device of the present invention, with cross-section shown in FIG. 2, we also placed a thin recombination layer at the hetero-interface, resulting in the following structure: ZnO:Al/iZnO/Perovskite/Rec. layer/CIGS/ohmic contact. A difference in the structure of the two devices is the replacement of the CdS layer in the standard CIGS device, and its associated material properties, with a perovskite layer and its associated material properties. The associated material properties include: permittivity, bandgap, electron affinity, electron and hole mobilities, n-type free-carrier concentration, deep defect concentration, the absorption coefficient as a function of wavelength, and thickness. For the purposes of this comparison, the deep defect density of the CdS was set to a much higher level than that of the perovskite layer, owing to the known low electronic quality that impedes the generation and collection of free-carriers in the CdS as evidenced in quantum efficiency measurements of typical CdS-CIGS PN heterojunction devices. Conversely, many perovskites materials are often cited in the literature as having good electronic quality, or low deep defect densities, and thus enabling the advantages of the present invention with a dual solar absorber. It should be understood that the present invention also enables lower electronic quality perovskites, as indicated by the modeling.

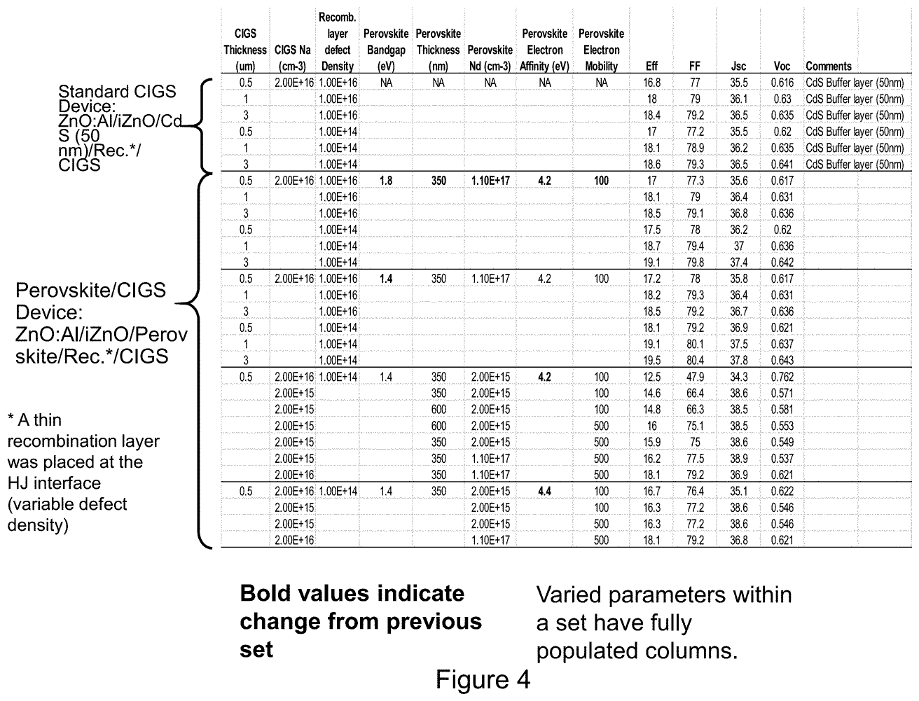

The device Eff (%), fill factor (FF), short-circuit current density (Jsc) and open-circuit voltage (Voc) results of this modeling and device emulation are shown in the table of FIG. 4 as a function of the perovskite material parameters, and the CIGS thickness and p-type free-carrier concentration (Na). The CIGS bandgap was set at 1.15 eV. The standard CIGS device results are shown in the first rows of the table, and as a function of recombination layer defect density and CIGS thickness and Na. The results for the dual absorber device with n-type perovskite take up the remainder of the table. Material parameter variables for the n-type perovskite were as follows: bandgap, electron affinity, electron and hole mobilities, n-type free-carrier concentration, and thickness. Also varied are the recombination layer defect density and the CIGS thickness and p-type carrier concentration. Bold values in the table indicate the changed parameter from previous set listed above it. Varied parameters within a set have fully populated columns.

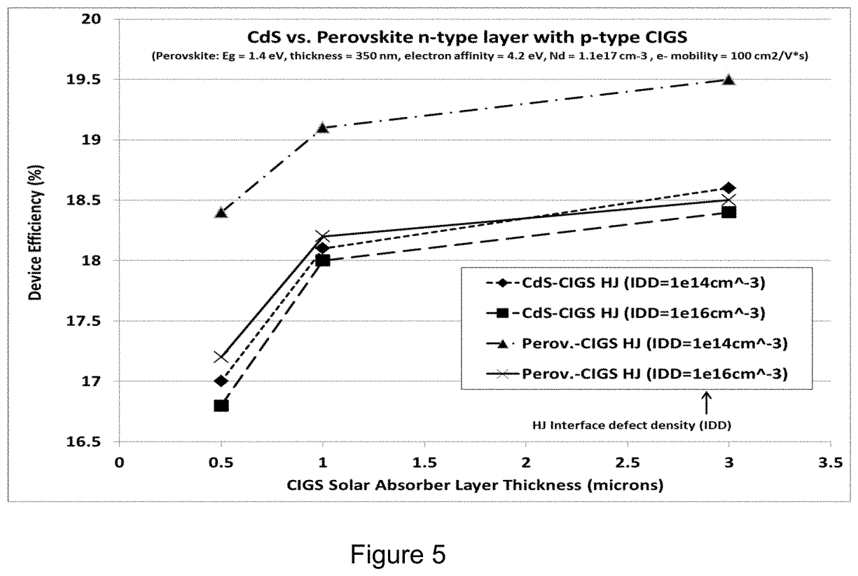

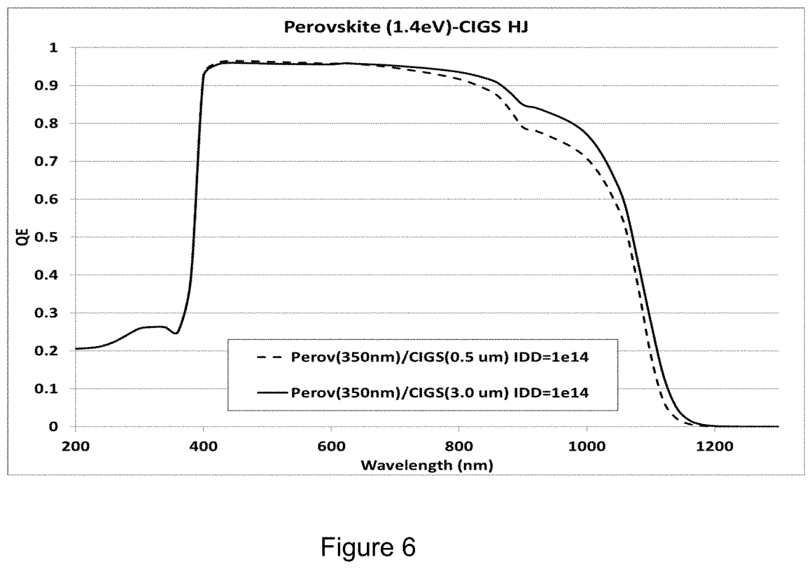

Using data from the table, FIG. 5 shows a plot of the device efficiency versus CIGS solar absorber thickness for both device types, and also for two different levels of interface layer defect density (IDD). The results show that the dual absorber device concept with n-type perovskite can enable higher efficiencies than the traditional CIGS device, owing to the better material quality as specified, and solar absorption of the perovskite over the CdS, and as long as the interface layer defect density (IDD) is not too large. The results also show that the dual absorber device with n-type perovskite is more sensitive to the IDD, so care will be needed to minimize the IDD. The dual absorber also enables a reduction in the thickness of the solar absorbing CIGS by half, without loss of performance compared to the traditional CIGS device. As an example, the device with the n-type perovskite and 0.5 um CIGS is as efficient as CdS-CIGS with CIGS thickness of 1 um. Traditional CIGS devices have CIGS thickness that is nominally much greater than 1 micron, and this modeling shows that the device performance improves more slowly with increasing thickness beyond 1 micron. With the dual absorber device concept with n-type perovskite, the increase in performance is even slower with increasing CIGS thickness beyond 1 micron, weakening the tradeoff between device performance and CIGS thickness or costs. Further insight is obtained from the Quantum efficiency (QE) plots from the dual absorber device modeling, FIG. 6, and show only marginal improvement in the long wavelength current collection by using a 3.0 micron thick CIGS solar absorber layer compared to a 0.5 micron thick CIGS solar absorber.

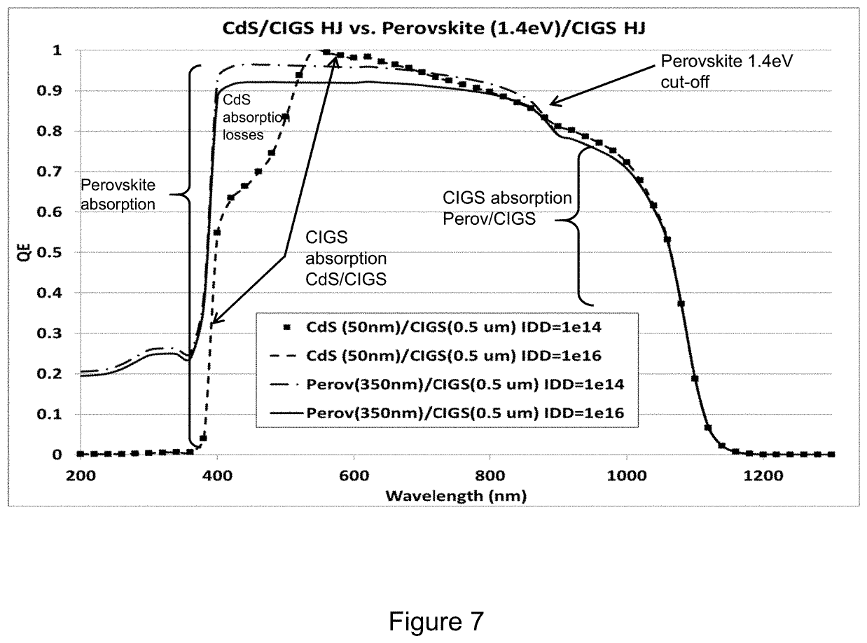

Modeled QE's of both device types are shown in FIG. 7, and for two different IDD levels that were used in FIG. 5. It should be noted that the CdS thickness was 50 nm in the traditional CIGS device, and the n-type perovskite layer thickness was 350 nm for the dual absorber device. The bandgap of the n-type perovskite was specified as 1.4 eV. For the traditional CIGS device, the QE results show the well-known notch in the short wavelength current collection, due to CdS absorption but without current collection, and the lack of dependence on the IDD (curves lay on top of each other). For the dual absorber layer device with n-type perovskite, there are no short wavelength losses as the perovskite as specified is enabling current collection (higher electronic quality). The other feature worth noting is the dip in the QE around 900 nm, which is due to the transmittance of the light through the perovskite due to the higher energy bandgap 1.4 eV. Longer wavelengths corresponding to energies lower 1.4 eV are mostly absorbed by the CIGS solar absorber layer. The dual absorber layer device is sensitive to the IDD, and the modeling shows that there is a loss of current collection from the perovskite solar absorber layer with higher IDD, but not the CIGS solar absorber layer.

In addition, the embodiments described in the following paragraphs are also a part of the present disclosure.

1a. A thin-film photovoltaic device, including:
a substrate for supporting the thin-film photovoltaic device;
a back contact layer disposed on the substrate:
a p-type solar absorber layer disposed on the back contact layer, wherein the p-type solar absorber layer includes one of a Group IB-IIIA-VIA.sub.2 material and a IIB-VIA material;
an n-type solar absorber layer disposed on and in contact with the p-type solar absorber layer, wherein the n-type solar absorber layer includes one of a Group IA-IVA-VIIA.sub.3 material, a Group IA.sub.2.-IV-VIIA.sub.6, and a Group W.sub.2.-I-M-VIIA.sub.6 material, wherein the Group W element includes an element selected from the group consisting of Group IA and Group IB elements of the periodic table, and an organic molecule, the Group M element includes an element selected from the group consisting of Group IIIA and Group VA elements of the periodic tables; and
a semi-transparent top contact layer disposed on the n-type solar absorber layer.
   2a. The thin-film photovoltaic device of paragraph 1a, wherein the p-type solar absorber layer includes CuInSe₂, CuGaSe₂, CuInS₂, CuGaS₂, or a combination thereof.
   3a. The thin-film photovoltaic device of paragraph 1a or 2a, wherein the p-type solar absorber layer includes at least one of a surface and a near surface region that is n-type.
   4a. The thin-film photovoltaic device of any one of paragraphs 1a-3a, wherein the p-type solar absorber layer has a thickness of 0.5 to 1.0 microns.
   5a. The thin-film photovoltaic device of any one of paragraphs 1a-4a, wherein the p-type solar absorber layer has a bandgap of less than 1.4 eV.
   6a. The thin-film photovoltaic device of any one of paragraph 1a-4a, wherein the p-type solar absorber layer has a bandgap of less than 1.2 eV.
   7a. The thin-film photovoltaic device of any one of paragraph 1a-6a, further including a buffer layer disposed between the n-type solar absorber layer and the semi-transparent top contact layer.
   8a. The thin-film photovoltaic device of any one of paragraph 1a-7a, wherein the n-type solar absorber layer includes a Group IA.sub.2.-IV-VIIA.sub.6 material, wherein the Group IA elements is at least one of Sodium, Potassium, Rubidium, and Cesium, the Group IV element is at least one of Silicon, Germanium, Tin, Lead, Titanium, and Zirconium, and the Group VIIA elements is at least one of Iodine, Bromine, Chlorine, and Fluorine;
   9a. The thin-film photovoltaic device of any one of paragraph 1a-7a, wherein the Group W element includes an organic molecule.
   10a. The thin-film photovoltaic device of any one of paragraph 9a, wherein the organic molecule is at least one of methyl-ammonium, phenyl-ethyl-ammonium, and Formamidinium.
   11a. The thin-film photovoltaic device of any one of paragraph 1a-7a, wherein the n-type solar absorber layer includes one of Cs₂SnI₆, Cs₂SnBr₆, Rb₂SnI₆, Rb₂SnBr₆, or a combination thereof.
   12a. The thin-film photovoltaic device of any one of paragraph 1a-7a, wherein the n-type solar absorber layer includes Cs₂TiI₆, Cs₂TiBr₆, Rb₂TiI₆, Rb₂TiBr₆, or a combiniation thereof.
   13a. The thin-film photovoltaic device of any one of paragraph 1a-7a, wherein the n-type solar absorber layer includes a Group I.sub.2.-I-IIIA-VIIA.sub.6 material, wherein the Group I element is at least one of Sodium, Potassium, Rubidium, Cesium, Copper, Silver, and Gold, the Group IIIA element is at least one of Boron, Aluminum, Gallium, Indium, and Thallium, and the Group VIIA elements is at least one of Iodine, Bromine, Chlorine, and Fluorine.
   14a. The thin-film photovoltaic device of any one of paragraph 1a-7a, wherein the n-type solar absorber layer includes of a Group W.sub.2.-I-IIIA-VIIA.sub.6 material, wherein the Group W element includes an organic molecule, the Group IIIA elements is at least one of Boron, Aluminum, Gallium, Indium, and Thallium, and the Group VIIA elements is at least one Iodine, Bromine, Chlorine, and Fluorine.
   15a. The thin-film photovoltaic device of paragraph 14a, wherein the organic molecule is at least one of methyl-ammonium, phenyl-ethyl-ammonium, and Formamidinium.
   16a. The thin-film photovoltaic device of any one of paragraph 1a-7a, wherein the n-type solar absorber layer includes a Group I.sub.2.-I-VA-VIIA.sub.6 material, wherein the Group I element is at least one of Sodium, Potassium, Rubidium, Cesium, Copper, Silver, and Gold, the Group VIIA elements is at least one of Iodine, Bromine, Chlorine, and Fluorine, and the Group VA elements includes at least one of Antimony and Bismuth.
   17a. The thin-film photovoltaic device of any one of paragraph 1a-7a, the n-type solar absorber layer includes Cs₂AgInI₆, Cs₂AgInBr₆, Rb₂AgInI₆, Rb₂AgInBr₆, or a combination thereof.
   18a. The thin-film photovoltaic device of any one of paragraph 1a-7a, wherein the n-type solar absorber layer includes a X₂Y′Y″Z₆ double perovskite material wherein the X elements are at least one of Cesium and Rubidium, the Y′ elements are at least one of copper, silver and indium, the Y″ elements are at least one of Antimony, and Bismuth, and the Z elements are at least one of Bromine and Iodine.
   19a. The thin-film photovoltaic device of any one of paragraph 1a-18a, wherein the n-type solar absorber layer has a thickness in the range of 0.3 to 0.6 microns.
   20a. The thin-film photovoltaic device of any one of paragraph 1a-18a, wherein the n-type solar absorber layer has a thickness in the range of 0.07 to 0.3 microns.
   21a. The thin-film photovoltaic device of any one of paragraph 1a-18a, wherein the n-type solar absorber layer has a thickness in the range of 0.03 to 0.07 microns.
   22a. The thin-film photovoltaic device of any one of paragraph 1a-21a, wherein the n-type solar absorber layer has a bandgap greater than the p-type absorber bandgap and less than 1.85 eV.
   23a. The thin-film photovoltaic device of any one of paragraph 1a-21a, wherein the n-type solar absorber layer has a bandgap greater than the p-type absorber bandgap and less than 1.65 eV.
   24a. The thin-film photovoltaic device of any one of paragraph 1a-23a, wherein the n-type solar absorber layer has a free carrier concentration in the range of 1e15 to 1e18 cm′.
   25a. The thin-film photovoltaic device of any one of paragraph 1a-23a, the n-type solar absorber layer has a free carrier concentration in the range of 5e15 to 1e18 cm³.
   26a. The thin-film photovoltaic device of any one of paragraph 1a-23a, wherein the n-type solar absorber layer has a free carrier concentration in the range of 1e16 to 1e18 cm³.
   27a. A method for forming a thin-film photovoltaic device, including:
disposing a back contact layer on a substrate;
disposing a p-type Group IB-IIIA-VIA.sub.2 solar absorber on the back contact layer, wherein the p-type Group IB-IIIA-VIA.sub.2 solar absorber includes two or more sublayers with each of the sublayers including one of a Group IB-IIIA-VIA.sub.2 material, a Group IIIA-VIA material, and a Group IB-VIA material;
performing an ion-beam surface smoothing treatment on the p-type solar absorber sublayer surface to form an ion-beam smoothed sublayer(s);
after performing the ion-beam surface smoothing treatment, disposing a final solar absorber sublayer on the ion-beam smoothed sublayer(s), wherein the final solar absorber sublayer includes one of a Group IB-IIIA-VIA.sub.2 material and a Group IIIA-VIA material;
disposing an n-type solar absorber layer on and in contact with the p-type solar absorber layer, the n-type solar absorber layer including one of a Group IA-IVA-VIIA.sub.3 material, a Group IA.sub.2.-IV-VIIA.sub.6, and a Group W.sub.2.-I-IIIA-VIIA.sub.6 material, wherein the Group W element includes an element selected from the group consisting of Group IA and Group IB elements of the periodic table, and an organic molecule; and
disposing a semi-transparent top contact layer on the n-type solar absorber layer.

Changes may be made in the above materials and devices without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present materials and devices, which, as a matter of language, might be said to fall there between.

What is claimed is:

1. A thin-film photovoltaic device, comprising:
a substrate for supporting the thin-film photovoltaic device;
a back contact layer disposed on the substrate:
a p-type solar absorber layer disposed on the back contact layer, wherein the p-type solar absorber layer comprises one of a Group IB-IIIA-VIA.sub.2 material and a IIB-VIA material;
an n-type solar absorber layer disposed on and in contact with the p-type solar absorber layer, wherein the n-type solar absorber layer comprises one of a Group IA-IVA-VIIA.sub.3 material, a Group IA.sub.2.-IV-VIIA.sub.6, and a Group W.sub.2.-I-M-VIIA.sub.6 material, wherein the Group W element comprises an element selected from the group consisting of Group IA and Group IB elements of the periodic table, and an organic molecule, the Group M element comprises an element selected from the group consisting of Group IIIA and Group VA elements of the periodic tables; and
a semi-transparent top contact layer disposed on the n-type solar absorber layer.

2. The thin-film photovoltaic device of claim 1, wherein the p-type solar absorber layer comprises CuInSe₂, CuGaSe₂, CuInS₂, CuGaS₂, or a combination thereof.

3. The thin-film photovoltaic device of claim 1, wherein the p-type solar absorber layer comprises at least one of a surface and a near surface region that is n-type.

4. The thin-film photovoltaic device of claim 1, wherein the p-type solar absorber layer has a thickness of 0.5 to 1.0 microns, and the p-type solar absorber layer has a bandgap of less than 1.4 eV.

5. The thin-film photovoltaic device of claim 1, further comprising a buffer layer disposed between the n-type solar absorber layer and the semi-transparent top contact layer.

6. The thin-film photovoltaic device of claim 1, wherein the n-type solar absorber layer comprises a Group IA.sub.2.-IV-VIIA.sub.6 material, wherein the Group IA elements is at least one of Sodium, Potassium, Rubidium, and Cesium, the Group IV element is at least one of Silicon, Germanium, Tin, Lead, Titanium, and Zirconium, and the Group VIIA elements is at least one of Iodine, Bromine, Chlorine, and Fluorine;

7. The thin-film photovoltaic device of claim 1, wherein the Group W element comprises an organic molecule, and the organic molecule is at least one of methyl-ammonium, phenyl-ethyl-ammonium, and Formamidinium.

8. The thin-film photovoltaic device of claim 1, wherein the n-type solar absorber layer comprises Cs₂SnI₆, Cs₂SnBr₆, Rb₂SnI₆, Rb₂SnBr₆, or a combination thereof.

9. The thin-film photovoltaic device of claim 1, wherein the n-type solar absorber layer comprises Cs₂TiI₆, Cs₂TiBr₆, Rb₂TiI₆, Rb₂TiBr₆, or a combiniation thereof.

10. The thin-film photovoltaic device of claim 1, wherein the n-type solar absorber layer comprises a Group I.sub.2.-I-IIIA-VIIA.sub.6 material, wherein the Group I element is at least one of Sodium, Potassium, Rubidium, Cesium, Copper, Silver, and Gold, the Group IIIA element is at least one of Boron, Aluminum, Gallium, Indium, and Thallium, and the Group VIIA elements is at least one of Iodine, Bromine, Chlorine, and Fluorine.

11. The thin-film photovoltaic device of claim 1, wherein the n-type solar absorber layer comprises of a Group W.sub.2.-I-IIIA-VIIA.sub.6 material, wherein the Group W element comprises an organic molecule and the organic molecule is at least one of methyl-ammonium, phenyl-ethyl-ammonium, and Formamidinium, the Group IIIA elements is at least one of Boron, Aluminum, Gallium, Indium, and Thallium, and the Group VIIA elements is at least one Iodine, Bromine, Chlorine, and Fluorine.

12. The thin-film photovoltaic device of claim 1, wherein the n-type solar absorber layer comprises a Group I.sub.2.-I-VA-VIIA.sub.6 material, wherein the Group I element is at least one of Sodium, Potassium, Rubidium, Cesium, Copper, Silver, and Gold, the Group VIIA elements is at least one of Iodine, Bromine, Chlorine, and Fluorine, and the Group VA element comprises at least one of Antimony and Bismuth.

13. The thin-film photovoltaic device of claim 1, the n-type solar absorber layer comprises Cs₂AgInI₆, Cs₂AgInBr₆, Rb₂AgInI₆, Rb₂AgInBr₆, or a combination thereof.

14. The thin-film photovoltaic device of claim 1, wherein the n-type solar absorber layer comprises a X₂Y′Y″Z₆ double perovskite material wherein the X elements are at least one of Cesium and Rubidium, the Y′ elements are at least one of copper, silver and indium, the Y″ elements are at least one of Antimony, and Bismuth, and the Z elements are at least one of Bromine and Iodine.

15. The thin-film photovoltaic device of claim 1, wherein the n-type solar absorber layer has a thickness in the range of 0.3 to 0.6 microns.

16. The thin-film photovoltaic device of claim 1, wherein the n-type solar absorber layer has a bandgap greater than the p-type absorber bandgap and less than 1.85 eV.

17. The thin-film photovoltaic device of claim 1, wherein the n-type solar absorber layer has a free carrier concentration in the range of 1e15 to 1e18 cm⁻³.

18. The thin-film photovoltaic device of claim 1, the n-type solar absorber layer has a free carrier concentration in the range of 5e15 to 1e18 cm⁻³.

19. The thin-film photovoltaic device of claim 1, wherein the n-type solar absorber layer has a free carrier concentration in the range of 1e16 to 1e18 cm⁻³.

20. A method for forming a thin-film photovoltaic device, comprising:
disposing a back contact layer on a substrate;
disposing a p-type Group IB-IIIA-VIA.sub.2 solar absorber on the back contact layer, wherein the p-type Group IB-IIIA-VIA.sub.2 solar absorber comprises two or more sublayers with each of the sublayers comprising one of a Group IB-IIIA-VIA.sub.2 material, a Group IIIA-VIA material, and a Group IB-VIA material;
performing an ion-beam surface smoothing treatment on the p-type solar absorber sublayer surface to form an ion-beam smoothed sublayer(s);
after performing the ion-beam surface smoothing treatment, disposing a final solar absorber sublayer on the ion-beam smoothed sublayer(s), wherein the final solar absorber sublayer comprises one of a Group IB-IIIA-VIA.sub.2 material and a Group IIIA-VIA material;
disposing an n-type solar absorber layer on and in contact with the p-type solar absorber layer, the n-type solar absorber layer comprising one of a Group IA-IVA-VIIA.sub.3 material, a Group IA.sub.2.-IV-VIIA.sub.6, and a Group W.sub.2.-I-M-VIIA.sub.6 material, wherein the Group W element comprises an element selected from the group consisting of Group IA and Group IB elements of the periodic table, and an organic molecule, the Group M element comprises an element selected from the group consisting of Group IIIA and Group VA elements of the periodic tables; and
disposing a semi-transparent top contact layer on the n-type solar absorber layer.
